(19) United States
(12) Patent Application Publication
(10) Pub. No.: US 2003/0122553 A1
(43) Pub. Date: Jul. 3, 2003

(54) Admittance sensor for mass detection

(75) Inventor: Herman Diaz Arias, Atizapan (MX)

Correspondence Address: Baker Botts L.L.P., Suite 600, 2001 Ross Avenue, Dallas, TX, 75201-2980, US

(73) Assignee: TRN Business Trust

(21) Appl. No.: 10/039,162

(22) Filed: Dec. 31, 2001

(51) Int. Cl. G01R 27/26

(52) U.S. Cl. 324/658

(57) ABSTRACT

An admittance sensor includes a voltage divider network having a probe and an associated variable virtual admittance. The voltage divider network is operable to receive pulses and transmit attenuated pulses. Each attenuated pulse has a respective attenuated pulse magnitude based, at least in part, upon a magnitude of the virtual admittance at approximately the respective time at which the attenuated pulses are transmitted. The admittance sensor also includes a level detector operable to receive the attenuated pulses from the voltage divider network and operable to generate output pulses corresponding to each of the attenuated pulses received which exceed a predetermined attenuated pulse magnitude. The admittance sensor also includes a pulse detector operable to receive the output pulses and generate a signal if at least one of the output pulses is not received for a predetermined period of time.

### TECHNICAL FIELD OF THE INVENTION

This invention relates to detection devices, and more particularly to an admittance sensor for mass detection.

### BACKGROUND OF THE INVENTION

Admittance is the ease with which current flows in an alternating-current circuit. Its magnitude depends on the resistance, capacitance and inductance of the circuit.

Charge transfer sensors are a variation of an admittance sensor and are generally related to capacitance measurement. The most common implementation is essentially an exercise in switching circuitry. A sensing electrode capacitor is charged with a reference voltage, and by simple switching that charge is transferred to a known capacitor.

Mechanical switches can be used only at very low sampling speeds. Such switches are bulky and have very high power consumption. Integrated metal oxide semiconductor field effect transistor (MOSFET) switches are small and are capable of high speed operation but have an internal resistance that is temperature dependent.

Some traditional charge transfer sensors have voltage regulators that do not have the transient response to charge large capacitance directly and at high sampling rates. The need for a good quality ground reference makes it difficult to use low sensitivity charge transfer sensors in applications like portable battery operated devices, fluid level measurement and gas mass evaluation, because poor quality ground greatly degrades range and sensitivity of conventional sensors.

A given mass of liquid, gas or solid material can be electrically characterized by a complex arrangement of resistance, capacitors and inductance. Many conventional charge transfer sensors cannot evaluate all these parameters in a single network.

### SUMMARY OF THE INVENTION

The present invention provides an admittance sensor for mass detection that substantially eliminates or reduces at least some of the disadvantages and problems associated with previous detection devices.

In accordance with a particular embodiment of the present invention, an admittance sensor includes a voltage divider network having a probe and an associated variable virtual admittance. The voltage divider network is operable to receive pulses and transmit attenuated pulses. Each attenuated pulse has a respective attenuated pulse magnitude based, at least in part, upon a magnitude of the virtual admittance at approximately the respective time at which the attenuated pulses are transmitted. The admittance sensor also includes a level detector operable to receive the attenuated pulses from the voltage divider network and operable to generate output pulses corresponding to each of the attenuated pulses received which exceed a predetermined attenuated pulse magnitude. The admittance sensor also includes a pulse detector operable to receive the output pulses and generate a signal if at least one of the output pulses is not received for a predetermined period of time.

In accordance with another embodiment, a method for detecting an admittance variation includes receiving pulses and transmitting attenuated pulses through a voltage divider network. The voltage divider network has a probe and an associated variable virtual admittance. Each attenuated pulse has a respective attenuated pulse magnitude based, at least in part, upon a magnitude of the virtual admittance at approximately the respective time at which the attenuated pulses are transmitted. The method also includes receiving the attenuated pulses from the voltage divider network using a level detector and generating output pulses using the level detector. The output pulses correspond to each of the attenuated pulses received which exceed a predetermined attenuated pulse magnitude. The method also includes generating an analog output based upon changes in the attenuated pulse magnitudes using an amplification system. The method also includes receiving the output pulses and generating a signal using a pulse detector if at least one of the output pulses is not received for a predetermined period of time.

Technical advantages of particular embodiments of the present invention include a sensor with the ability to detect an object approaching a probe based on variations in the admittance of the area surrounding the probe. Accordingly, changes in any of a number of characteristics affecting admittance, including capacitance, resistance or inductance, can lead to sensor notification of an approaching object.

Another technical advantage of particular embodiments of the present invention is an admittance sensor with a controlled feedback loop for detection of objects approaching a probe at a particular speed. Accordingly, the sensor can be used in various applications, such as air bag deployment and automobile security systems.

Still another technical advantage of particular embodiments of the present invention includes an admittance sensor which consumes a low amount of power during operation. Accordingly, the sensor can be battery operated at maximum sensitivity and may thus be useful in battery operated security systems.

Other technical advantages will be readily apparent to one skilled in the art from the following figures, descriptions and claims. Moreover, while specific advantages have been enumerated above, various embodiments may include all, some or none of the enumerated advantages.

### BRIEF DESCRIPTION OF THE DRAWINGS

FIG. 1 is a diagram illustrating an admittance sensor in accordance with a particular embodiment of the present invention;

FIG. 2 is a schematic diagram illustrating electronic circuitry of an admittance sensor in accordance with a particular embodiment of the present invention; and

FIG. 3 is a graph illustrating the relationship between a control voltage and a pulse width of an admittance sensor in accordance with an embodiment of the present invention.

### DETAILED DESCRIPTION OF THE INVENTION

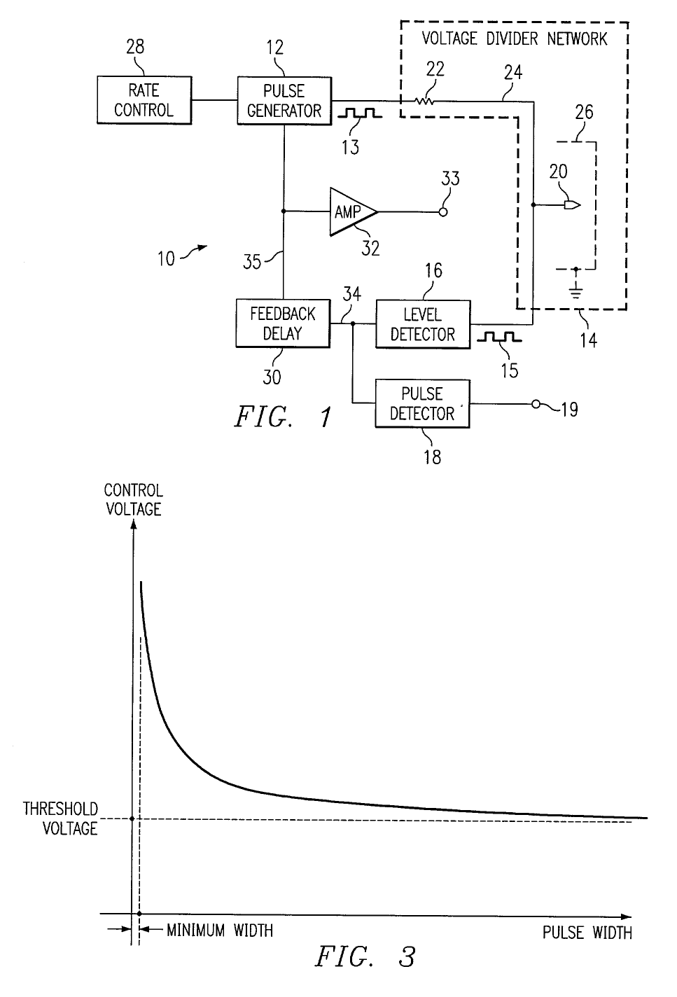

FIG. 1 illustrates an admittance sensor 10 in accordance with a particular embodiment of the present invention. Admittance sensor 10 may be used to measure the admittance near a probe 20 or to give a warning signal when a body of certain characteristics approaches probe 20.

Admittance sensor 10 includes a pulse generator 12. Pulse generator 12 generates a pulse train 13 which is received by a voltage divider network 14. Voltage divider network 14 includes probe 20 and an associated virtual admittance of the surrounding media around probe 20. Pulse train 13 enters voltage divider network 14. Voltage divider network 14 then transmits attenuated pulse train 15 which flows to a level detector 16.

Level detector 16 may produce output pulses 34 with pulse widths based upon magnitudes of pulse train 15. Such magnitudes reflect the virtual admittance of the area around probe 20 at approximately the time at which pulse train 15 is transmitted by voltage divider network 14. If the virtual admittance around probe 20 subsequently changes, then subsequent periods of output pulses 34 will change in proportion to the change in virtual admittance. If an object comes into proximity with probe 20, the virtual admittance of the area surrounding probe 20 decreases. If such decrease is dramatic enough, then level detector 16 may not produce an output pulse for a certain period of time. In accordance with a particular embodiment, this will trigger pulse detector 18 to produce a signal output 19 to notify a user that an object is approaching probe 20.

Admittance sensor 10 also includes an amplification system 32. Amplification system 32 may produce an analog output 33 displaying the magnitude of a voltage level 35 output by a feedback delay 30. Voltage level 35 is based upon the pulse widths of output pulses 34. As stated above, such pulse widths are based upon magnitudes of pulse train 15 which reflect the virtual admittance of the area around probe 20 at approximately the time at which pulse train 15 is transmitted by voltage divider network 14. Thus, analog output 33 may reflect variation in admittance around probe 20. Particular embodiments of the present invention may include one or both of signal output 19 and analog output 33 to detect a change in the virtual admittance and the relative magnitude of such change, respectively.

Using the virtual admittance of the area surrounding probe 20 as a basis for signal output 19 of pulse detector 18 and analog output 33 of amplification system 32 is useful since admittance comprises capacitance, resistance and inductance in a single parameter. Thus, changes in any of these characteristics in the area surrounding probe 20 may produce an output based on the change in admittance resulting from an object coming into proximity with probe 20.

Admittance sensor 10 also includes rate control 28. Rate control 28 controls the frequency of pulse generator 12. Voltage divider network 14 also includes a resistor 22, a conductor 24 and electrical impedance to ground of an area 26 surrounding probe 20. Probe 20 of voltage divider network 14 may comprise any electrically conductive material, such as a rod, a plate, a pipe, a needle or a sphere. The size of probe 20 may vary without reducing sensitivity.

As stated above, after attenuation of pulse train 13, voltage divider network 14 transmits attenuated pulse train 15 into level detector 16. If the amplitude of pulse train 15 is higher than a reference voltage of level detector 16, then level detector 16 will produce output pulses 34 having a similar train of pulses but with a smaller period than the period of pulse train 15. The period of output pulses 34 will be proportional to the variations in admittance of the space around probe 20.

If a mass approaches probe 20, then the virtual admittance of the area surrounding probe 20 will decrease, resulting in a reduction in amplitude of pulse train 15 with respect to pulse train 13. If the amplitude of pulse train 15 is not higher than a reference voltage, then level detector 16 will not produce an output pulse for a certain period of time. If there is no output pulse of level detector 16 for a predetermined period of time, then pulse detector 18 may produce signal output 19 to alert a user of an object approaching probe 20 or to trigger a device. The reference voltage may be set such that pulse detector 18 produces signal output 19 based on certain characteristics of an object approaching probe 20. Such characteristics may include any characteristic which may affect the virtual admittance of the area surrounding probe 20, such as the velocity or the mass of the object.

Pulse detector 18 may be adjusted such that it may respond to any number of missing pulses. Such adjustment may be made based on whether a user desires to detect a slow or fast approaching object through pulse detector 18.

Admittance sensor 10 also includes feedback delay 30. Output pulses 34 of level detector 16 provide a feedback signal. Feedback delay 30 delays the pulse train of output pulses 34 and transforms the pulse period of output pulses 34 to voltage level 35 which enters pulse generator 12. The magnitude of the voltage level change is proportional to the variations in admittance in the area surrounding probe 20. The delay of feedback delay 30 can be adjusted so that admittance sensor 30 can evaluate both slow and fast objects approaching probe 20. The use of feedback delay 30 may allow for the detection of small admittance changes at probe 20 and automatic adjustment to slow-changing environmental conditions around the probe.

As stated above, amplification system 32 may produce an analog output 33 which in effect displays the magnitude of the variation in admittance at probe 20. This information can be used, for example, to measure gas flow in pipes and the level of fluids contained in tanks.

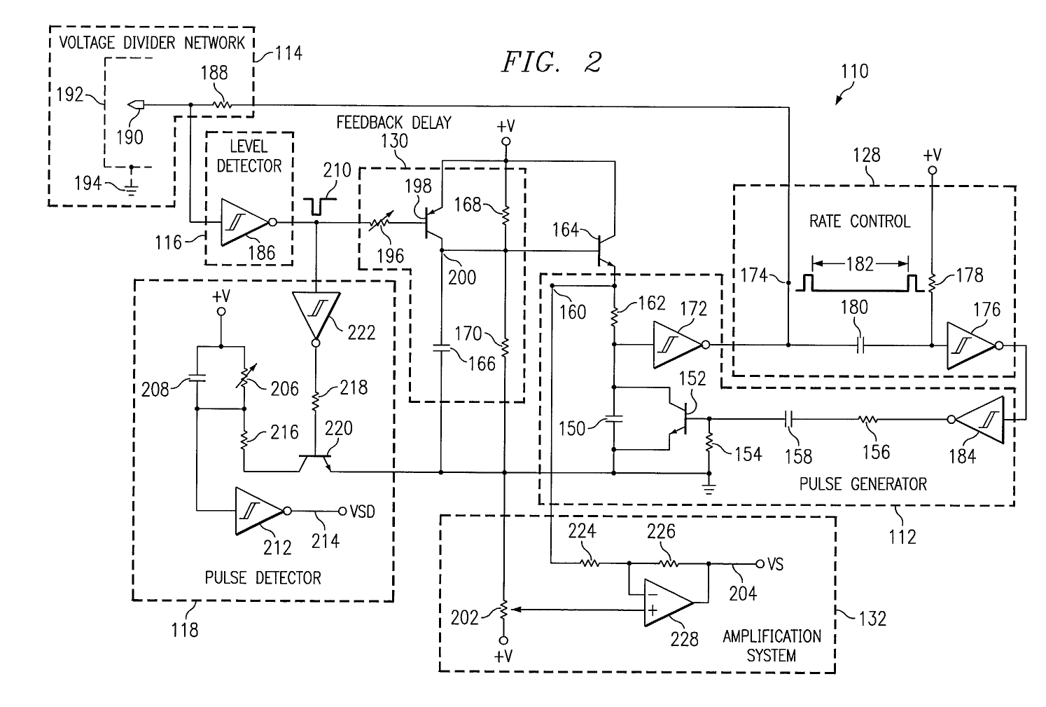

As an example, if admittance sensor 10 is used to measure gas flow in a pipe, probe 20 would be located inside the pipe. A reference level may be set by a potentiometer (illustrated in FIG. 2) when there is no flow in the pipe. When the gas flow begins, the admittance of the area surrounding probe 20 decreases. Output 33 displays the proportional variation in admittance of the area surrounding probe 20.

In another example, if admittance sensor 10 is used to measure the level of a fluid contained in a tank, probe 20 may be a rod placed vertically into the tank. As the level of the fluid rises, the fluid covers a larger portion of the rod. Thus, the admittance of the area surrounding the rod decreases, and output 33 displays the magnitude of this decrease.

Another application of an admittance sensor in accordance with an embodiment of the present invention may be in air bag deployment in automobiles. In this situation, the admittance sensor may be used to alert a pyrotechnic device that controls the air bag seconds before the impact of an object with the automobile. The device may be detonated at this time, reducing the risk of injuries to passengers in the automobile. This application may also allow for the use of less explosive pyrotechnic devices since device does not have to wait until impact to detonate. Several probes may be used with the admittance sensor to protect the automobile from different directions. The feedback delay of the admittance sensor may be set such that the admittance sensor may respond to a certain momentum (p=mv) at a preset distance from a probe.

Other applications of an admittance sensor in accordance with particular embodiments of the present invention may include automobile and museum security devices. For example, an admittance sensor may be used to trigger an automobile alarm when a person approaches the automobile. An admittance sensor could also be mounted in a museum proximate to an art work to alert security personnel when a person approaches the art work.

Admittance sensor 10 consumes a low amount of power during operation and thus may be used in battery operated devices, such as battery operated security systems.

FIG. 2 is a schematic diagram illustrating electronic circuitry of an admittance sensor 110 in accordance with a particular embodiment of the present invention. Admittance sensor 110 includes a pulse generator 112, a voltage divider network 114, a level detector 116, a pulse detector 118, a rate control 128 and a feedback delay 130.

Pulse generator 112 includes a capacitor 150 electrically coupled to a transistor 152. Pulse generator 112 also includes resistors 154, 156 and 162, capacitor 158 and inverters 172 and 184. In operation, capacitor 150 is discharged by transistor 152. The discharge pulse at the base of transistor 152 is provided by the resistance-capacitance network of resistor 154, resistor 156 and capacitor 158. The width of this pulse may be very narrow (e.g., a few nanoseconds).

After discharging, capacitor 150 begins to charge. A control voltage 160 and resistor 162 set the rate of charge. Capacitor 150 and resistor 162 have fixed values, while control voltage 160 at the emitter of a transistor 164 is variable. Control voltage 160 follows the voltage variations of the voltage across a capacitor 166. Resistors 168 and 170 are used to set a start up voltage at the base of transistor 164 and a discharge path to capacitor 166.

When the voltage of capacitor 150 reaches a high threshold level of Schmitt-trigger inverter 172, an output pulse 174 goes low. The elapsed time between this event and the end of the discharge pulse at the base of transistor 152 sets the width of output pulse 174.

Control voltage 160 is always higher than the threshold voltage of inverter 172; but when the two values approach, the width of output pulse 174 becomes very large. In a noise-free environment this width can be almost infinite.

Rate control 128 includes an inverter 176, a resistor 178 and capacitor 180. Rate control 128 is electrically coupled to a voltage source. When output pulse 174 of inverter 172 goes low, the output of inverter 176 goes high during a separation time 182 set by resistor 178 and capacitor 180. Separation time 182 is a time between the pulses of output pulse 174. When capacitor 180 charges to the high level threshold of inverter 176, the output of inverter 176 goes low. Inverter 184 generates a reset pulse discharging capacitor 150, and a new cycle begins.

Voltage divider network 114 includes resistor 188, probe 190, an area 192 surrounding probe 190 and virtual ground 194. Voltage divider network 114 attenuates output pulse 174 based upon the admittance of area 192 surrounding probe 190. Output pulse 174 then flows to level detector 116.

Level detector 116 includes an inverter 186. After a pulse has been attenuated by voltage divider network 114, if it is high enough to change the output of inverter 186 from high to low then pulses 210 are generated having a width proportional to the difference between the height of the pulses at the input of inverter 186 and the threshold level of the inverter.

Feedback delay 130 includes resistors 196, 168 and 170, a capacitor 166 and transistors 164 and 198. Feedback delay 130 is electrically coupled to a voltage source. Resistor 196 converts pulses 210 into current pulses amplified by transistor 198, and the voltage across capacitor 166 increases. Transistor 164 completes the feedback loop increasing control voltage 160 and thus making the width of output pulse 174 smaller.

The procedure automatically reverses if output pulse 174 does not have the required height after being attenuated by voltage divider network 114. In this case, there is no charging pulse at a point 200, and capacitor 166 discharges slowly, draining current by the network of resistors 168 and 170 and the base of transistor 164.

Amplification system 132 includes potentiometer 202, resistors 224 and 226 and amplifier 228. Amplification system 132 is electrically coupled to a voltage source. Control voltage 160 is amplified by amplification system 132 to give an output 204 proportional to the admittance variation resulting from a mass near probe 190. The mass may be ionized gas, a fluid or a solid. Output 204 may be logarithmic to allow for a wide range of input capacitance without changing the components of admittance sensor 110. Potentiometer 202 is used to set a reference level in amplification system 132 making output 204 adaptable to various applications.

Pulse detector 118 includes resistors 206, 216 and 218, a capacitor 208, a transistor 220 and inverters 212 and 222. Resistor 196 can be used to adjust the response time of feedback delay 130. If the response time of feedback delay 130 is very fast, the movement of slow objects will not be detected by pulse detector 118.

Additional gain control is given by resistor 206. Resistor 206 controls the discharging time of capacitor 208 if pulses 210 are interrupted over a preset time. Voltage capacitor 208 can reach the threshold of the input of inverter 212 switching its output from high to low. If resistor 196 has a very low resistance, feedback voltage 200 quickly compensates any increment in the admittance around probe 190, and output 214 can be set to detect only fast approaching objects.

FIG. 3 illustrates the relationship between the control voltage 160 and the width of output pulse 174, both of FIG. 2. When the control voltage approaches the threshold level of inverter 172 of FIG. 2, the curve becomes almost horizontal, increasing the pulse width to several decades of magnitude with respect to the minimum pulse width. As illustrated, working near the threshold voltage of inverter 172 of FIG. 2 can provide a very wide range of pulse widths with which to operate.

Although the present invention has been described in detail, various changes and modifications may be suggested to one skilled in the art. It is intended that the present invention encompass such changes and modifications as falling within the scope of the appended claims.

What is claimed is:

1. An admittance sensor, comprising:
a voltage divider network having a probe and an associated variable virtual admittance;
the voltage divider network being operable to receive pulses and transmit attenuated pulses, each attenuated pulse having a respective attenuated pulse magnitude based, at least in part, upon a magnitude of the virtual admittance at approximately the respective time at which the attenuated pulses are transmitted;
a level detector operable to receive the attenuated pulses from the voltage divider network and further operable to generate output pulses corresponding to each of the attenuated pulses received which exceed a predetermined attenuated pulse magnitude;
a pulse detector operable to receive the output pulses and generate a signal if at least one of the output pulses is not received for a predetermined period of time.

2. The admittance sensor of claim 1, further comprising an amplification system operable to generate an analog output based upon changes in the attenuated pulse magnitudes.

3. The admittance sensor of claim 1, wherein the magnitude of the virtual admittance at approximately the respective time at which the attenuated pulses are transmitted will change in response to an object approaching the probe, the object having a characteristic.

4. The admittance sensor or claim 3, wherein the characteristic comprises at least one of a velocity of the object and a mass of the object.

5. The admittance sensor of claim 1, further comprising a pulse generator operable to generate the pulses.

6. The admittance sensor of claim 5, further comprising a rate control operable to control the frequency of the pulses generated by the pulse generator.

7. The admittance sensor of claim 1, further comprising a feedback delay operable to convert a period of the output pulses to a voltage.

8. The admittance sensor of claim 7, wherein the feedback delay is further operable to delay the output pulses of the level detector.

9. An admittance sensor, comprising:
a voltage divider network having a probe and an associated variable virtual admittance;
the voltage divider network being operable to receive pulses and transmit attenuated pulses, each attenuated pulse having a respective attenuated pulse magnitude based, at least in part, upon a magnitude of the virtual admittance at approximately the respective time at which the attenuated pulses are transmitted;
a level detector operable to receive the attenuated pulses from the voltage divider network and further operable to generate output pulses corresponding to each of the attenuated pulses received which exceed a predetermined attenuated pulse magnitude; and
an amplification system operable to generate an analog output based upon changes in the attenuated pulse magnitudes.

10. The admittance sensor of claim 9, further comprising a pulse detector operable to receive the output pulses and generate a signal if at least one of the output pulses is not received for a predetermined period of time.

11. The admittance sensor of claim 9, wherein the magnitude of the virtual admittance at approximately the respective time at which the attenuated pulses are transmitted will change in response to an object approaching the probe, the object having a characteristic.

12. The admittance sensor of claim 11, wherein the characteristic comprises at least one of a velocity of the object and a mass of the object.

13. The admittance sensor of claim 9, further comprising a pulse generator operable to generate the pulses.

14. The admittance sensor of claim 13, further comprising a rate control operable to control the frequency of the pulses generated by the pulse generator.

15. The admittance sensor of claim 9, further comprising a feedback delay operable to convert a period of the output pulses to a voltage.

16. The admittance sensor of claim 15, wherein the feedback delay is further operable to delay the output pulses of the level detector.

17. A method for detecting an admittance variation, comprising:
receiving pulses and transmitting attenuated pulses through a voltage divider network, the voltage divider network having a probe and an associated variable virtual admittance;
wherein each attenuated pulse has a respective attenuated pulse magnitude based, at least in part, upon a magnitude of the virtual admittance at approximately the respective time at which the attenuated pulses are transmitted;
receiving the attenuated pulses from the voltage divider network using a level detector;
generating output pulses using the level detector, the output pulses corresponding to each of the attenuated pulses received which exceed a predetermined attenuated pulse magnitude;
generating an analog output based upon changes in the attenuated pulse magnitudes using an amplification system; and
receiving the output pulses and generating a signal using a pulse detector if at least one of the output pulses is not received for a predetermined period of time.

18. The admittance sensor of claim 17, wherein the magnitude of the virtual admittance at approximately the respective time at which the attenuated pulses are transmitted will change in response to an object approaching the probe, the object having a characteristic.

19. The admittance sensor or claim 18, wherein the characteristic comprises at least one of a velocity of the object and a mass of the object.

20. The admittance sensor of claim 17, further comprising generating the pulses using a pulse generator.

21. The admittance sensor of claim 17, controlling the frequency of the generated pulses using a rate control.

22. The admittance sensor of claim 17, further comprising converting a period of the output pulses to a voltage using the feedback delay.

23. The admittance sensor of claim 22, further comprising delaying the output pulses of the level detector using a feedback delay.
